(19) United States
(12) Patent Application Publication
(10) Pub. No.: US 2024/0293952 A1
(43) Pub. Date: Sep. 5, 2024

(54) RECYCLING APPARATUS FOR SOLAR PANEL AND METHOD OF RECYCLING SOLAR PANEL

(71) Applicant: SHINTORAKOUSAN, CO., LTD., Osaka (JP)

(72) Inventor: Takashi KIMURA, Osaka (JP)

(21) Appl. No.: 18/578,400

(22) PCT Filed: Jul. 14, 2022
(86) PCT No.: PCT/JP2022/027683

§ 371 Date: Jan. 11, 2024

(30) Foreign Application Priority Data
Jul. 29, 2021 (JP) 2021-123836

(51) Int. Cl. B26F 3/00

(52) U.S. Cl. CPC B26F 3/008

(57) ABSTRACT

A recycling apparatus is composed of a high-pressure water generating device, generating high-pressure water, and a jet nozzle that is connected to the high-pressure water generating device and spouts the high-pressure water toward a solar panel. The jet nozzle spouts the high-pressure water toward a back surface of the solar panel to remove a layer of the solar panel until a cover glass included in the solar panel.

### FIELD OF THE INVENTION

The present invention relates to an apparatus for and a method of processing a used solar panel to recycle the used solar panel.

### BACKGROUND ART

In recent years, solar power generation has been increasingly selected as one of the countermeasure for satisfying restrictions imposed on carbon dioxide emissions and ecological consciousness enhanced in commercial activities.

With this trend, technological development has been also progressed for a method of processing a used solar panel for solar power generation.

For example, a method employed in general for processing a used solar panel is the one that the solar panel is entirely thrown in a crusher to be broken into pieces.

On the other hand, Patent Literature 1 discloses a technology of peeling a cover glass from a structure (solar cell, etc.) in a used solar panel with a peeling tool (blade) after heating and softening the used solar panel by annealing.

### CITATION LIST

### Patent Literature

Patent Literature 1: Japan Patent No. 6104141

### SUMMARY OF THE INVENTION

### Technical Problem

However, the crushing processing of entirely breaking the solar panel into pieces has posed not only a drawback that carbon dioxide is emitted with crushing but also a drawback that it takes great effort to perform recycling such as recovery of valuable resources after the crushing processing.

On the other hand, the method of processing a solar panel disclosed in Patent Literature 1 has posed a drawback that a great amount of energy is required for annealing.

The present invention has been developed in view of the drawbacks of the prior arts described above. Therefore, it is a main object of the present invention to provide a recycling apparatus for a solar panel and a method of recycling a solar panel, whereby it is made easy to perform recycling after processing, and simultaneously, such drawbacks as emissions of carbon dioxide and necessity for a great amount of energy are not posed.

### Solution to Problem

According to an aspect of the present invention, a recycling apparatus for a solar panel is provided. The recycling apparatus includes a high-pressure water generating device, generating high-pressure water, and a jet nozzle that is connected to the high-pressure water generating device and spouts the high-pressure water toward a solar panel.

Preferably, the jet nozzle spouts the high-pressure water toward a back surface of the solar panel to remove a layer of the solar panel until a cover glass included in the solar panel.

Besides, according to another aspect of the present invention, a method of recycling a solar panel is provided. The method includes processing the solar panel with high-pressure water generated by a high-pressure water generating device. The high-pressure water is spouted from the high-pressure water generating device through a jet nozzle toward the solar panel.

Preferably, the high-pressure water is spouted toward a back surface of the solar panel to remove a layer of the solar panel until a cover glass included in the solar panel.

### Effects of Invention

Overall, according to the present invention, the solar panel is configured to be processed with the high-pressure water generated by the high-pressure water generating device: hence, it is possible to provide the recycling apparatus and the recycling method, whereby it is made easy to perform recycling after processing, and simultaneously, it is made possible to avoid such drawbacks as emissions of carbon dioxide and necessity for a great amount of energy.

### BRIEF DESCRIPTION OF THE DRAWINGS

FIG. 1 this figure is a diagram entirely showing a recycling apparatus 10 to which the present invention is applied:

FIG. 2 this figure is a diagram exemplifying a structure of a solar panel 100 to be processed with the recycling apparatus 10; and

FIG. 3 this figure is a diagram exemplifying a state of the solar panel 100 from which some of layers have been removed until a cover glass 104 with the recycling apparatus 10.

### DETAILED DESCRIPTION OF EMBODIMENTS

### Configuration of Recycling Apparatus 10

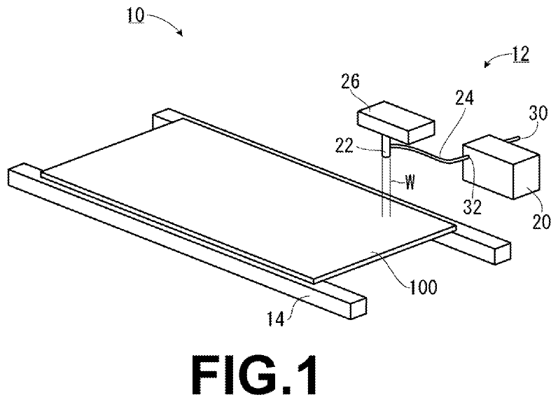

A practical example will be hereinafter explained regarding a recycling apparatus 10 for a solar panel 100, to which the present invention is applied. As shown in FIG. 1, the recycling apparatus 10 includes a high-pressure water jet unit 12 and a work holding unit 14.

The high-pressure water jet unit 12 includes a high-pressure water generating device 20, a jet nozzle 22, a high-pressure water hose 24, and a jet nozzle moving device 26.

The high-pressure water generating device 20 is a device for generating high-pressure water W by pressurizing water supplied thereto. The high-pressure water generating device 20 includes a water receiving port 30 and a high-pressure water discharge port 32.

The jet nozzle 22 is a member for spouting the high-pressure water W supplied thereto from the high-pressure water generating device 20. The jet nozzle 22 is connected to the high-pressure water generating device 20 through the high-pressure water hose 24.

The jet nozzle moving device 26 is a device for shifting the position of the jet nozzle 22 with respect to the solar panel 100 as a work. Here, a type of moving device, enabled to move the jet nozzle 22 in a three-dimensional manner, is used as the jet nozzle moving device 26. Obviously, if it does not matter that the jet nozzle 22 is remote from the work (solar panel) 100 at a constant distance, a type of moving device, horizontally moving the jet nozzle 22 in a two-dimensional manner, may be used as the jet nozzle moving device 26.

Moreover, the jet nozzle moving device 26 may move the high-pressure water jet unit 12 together with the jet nozzle 22. Alternatively, the jet nozzle moving device 26 may move only the jet nozzle 22 by configuring the high-pressure water jet unit 12 as a stationary type.

The work holding unit 14 is a unit for holding the work (solar panel) 100. Besides, the work holding unit 14 may be provided with a function of horizontally moving the work (solar panel) 100 in a two-dimensional manner on an as-needed basis.

### Configuration of Solar Panel 100

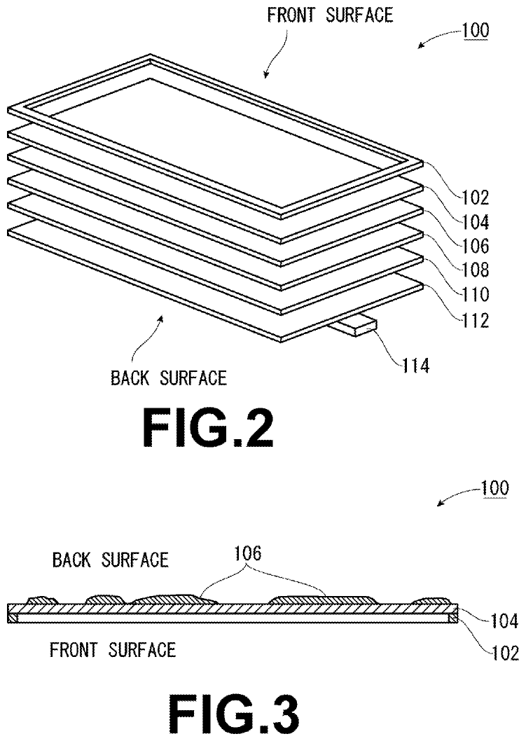

Next, a general structure of the solar panel 100 will be briefly explained with FIG. 2. In general, the solar panel 100 is formed by sequentially laminating, from the front surface thereof for receiving sunlight to the back surface thereof, a frame 102, a cover glass 104, a first sealant layer 106, a solar battery cell 108, a second sealant layer 110, a back sheet 112, and a junction box 114. It should be noted that the structure of the solar panel 100 to be processed by the recycling apparatus 10 according to the present exemplary embodiment is not limited to this. Another layer may be added to the structure described above: alternatively, any of the layers of the structure described above may be omitted as long as at least the cover glass 104 and the solar battery cell 108 are included in the layers of the structure described above.

An ethylene-vinyl acetate (EVA) copolymer resin, for instance, is used as a sealant for the first sealant layer 106 and that for the second sealant layer 110; however, another material may be employed as the sealant for each layer 106, 110.

Likewise, plastic such as polyethylene terephthalate (PET), for instance, is used as a material of the back sheet 112: however, another material may be employed as the material of the back sheet 112.

There are a variety of types of solar panels other than the solar panel 100 having such a general structure as described above: a double-sided type, a bendable type, a silicon-based or compound-based type (exemplified as another material type), and so forth. The recycling apparatus 10 and the recycling method according to the present invention are compatible with processing all the types of solar panels herein described.

### Processing of Solar Panel 100 by Recycling Apparatus 10

Processing of the solar panel 100 by the recycling apparatus 10 according to the present exemplary embodiment will be explained. First, the work (solar panel) 100 is put on the work holding unit 14 of the recycling apparatus 10 and is then fixed thereto on an as-needed basis. In this case, the solar panel 100 is put on the work holding unit 14, while the back surface thereof faces the high-pressure water jet unit 12.

Thereafter, the high-pressure water W generated by the high-pressure water generating device 20 is spouted from the jet nozzle 22 through the high-pressure water hose 24 toward the back surface of the solar panel 100.

The layers of the solar panel 100 are removed from the back surface until the cover glass 104 with the spouted high-pressure water W.

Here, a state “the layers of the solar panel 100 are removed until the cover glass 104” refers to a state that amongst the layers of the solar panel 100, some laminated from the back surface to the solar battery cell 108 are removed, whereby the cover glass 104 is exposed at least in part as shown in FIG. 3. In other words, the first sealant layer 106 is not required to be removed completely: hence, even when the first sealant layer 106 is left in part on the cover glass 104, this is considered as the state “the layers of the solar panel 100 are removed until the cover glass 104”.

As described above, when removing the layers of the solar panel 100 is completed until the cover glass 104 in a position struck by the spouted high-pressure water W, the jet nozzle moving device 26 moves the jet nozzle 22 to shift the position struck by the high-pressure water W. After the movement, the layers of the solar panel 100 are similarly removed until the cover glass 104 in the shifted position.

When the high-pressure water W is spouted from the jet nozzle 22 as described above, the jet nozzle moving device 26 may be configured to stop moving the jet nozzle 22, or alternatively, may be configured to move the jet nozzle 22, while the high-pressure water W is kept spouted from the jet nozzle 22.

### Features of Recycling Apparatus 10

The recycling apparatus 10 according to the present exemplary embodiment is configured to process the solar panel 100 with the high-pressure water W generated by the high-pressure water generating device 20; hence, it is made easy to perform recycling after processing, and simultaneously, it is made possible to avoid such drawbacks as emissions of carbon dioxide and necessity for a great amount of energy.

Besides, the recycling apparatus 10 is configured to remove the layers of the solar panel 100 until the cover glass 104 by spouting the high-pressure water W toward the back surface of the solar panel 100: hence, chances are lowered that the cover glass 104 is unfortunately broken into pieces during processing, whereby it is made easy to recycle the cover glass 104 and the frame 102 after processing the solar panel 100.

### MODIFICATION 1

In the exemplary embodiment described above, the layers of the solar panel 100 are removed until the cover glass 104 by spouting the high-pressure water W toward the back surface of the solar panel 100: alternatively, the layers of the solar panel 100, including the cover glass 104, may be entirely crushed by spouting the high-pressure water W toward the front surface of the solar panel 100. This is because even with the alternative configuration, it is made easy to perform recycling after processing, and simultaneously, it is made possible to avoid such drawbacks as emissions of carbon dioxide and necessity for a great amount of energy. For example, in such a situation as processing the solar panel 100 damaged or broken in a disaster or so forth, the high-pressure water W is supposed to be spouted toward both the front and back surfaces of the solar panel 100.

Obviously, it is preferable to remove the layers of the solar panel 100 until the cover glass 104 by spouting the high-pressure water W toward the back surface of the solar panel 100 as described in the exemplary embodiment described above.

It should be understood that the embodiments herein disclosed are illustrative only and are not restrictive in all aspects. It is intended that the scope of the present invention is indicated by the appended claims rather than the explanation described above and encompasses all the changes that come within the meaning and the range of equivalents of the appended claims.

### REFERENCE SIGNS LIST

10 . . . Recycling apparatus, 12 . . . High-pressure water jet unit, 14 . . . Work holding unit, 20 . . . High-pressure water generating device, 22 . . . Jet nozzle, 24 . . . High-pressure water hose, 26 . . . Jet nozzle moving device, 30 . . . Water receiving port, 32 . . . High-pressure water discharge port, 100 . . . Solar panel (work), 102 . . . Frame, 104 . . . Cover glass, 106 . . . First sealant layer, 108 . . . Solar battery cell, 110 . . . Second sealant layer, 112 . . . Back sheet, 114 . . . Junction box

What is claimed is:

1. A recycling apparatus for a solar panel, comprising:
a high-pressure water generating device generating high-pressure water, and
a jet nozzle connected to the high-pressure water generating device, the jet nozzle spouting the high-pressure water toward the solar panel, wherein
the jet nozzle spouts the high-pressure water toward a back surface of the solar panel to remove a layer of the solar panel until a cover glass included in the solar panel.

2. A method of recycling a solar panel, comprising:
processing the solar panel with high-pressure water generated by a high-pressure water generating device, the high-pressure water spouted from the high-pressure water generating device through a jet nozzle toward a back surface of the solar panel to remove a layer of the solar panel until a cover glass included in the solar panel.
